(19) United States
(12) Patent Application Publication
(10) Pub. No.: US 2026/0129867 A1
(43) Pub. Date: May 7, 2026

(54) MAGNETORESISTIVE RANDOM ACCESS MEMORY AND METHOD FOR FABRICATING THE SAME

(71) Applicant: UNITED MICROELECTRONICS CORP., Hsin-Chu City (TW)

(72) Inventors: Hui-Lin Wang, Taipei City (TW); Ching-Hua Hsu, Kaohsiung City (TW); Chen-YI Weng, New Taipei City (TW); Che-Wei Chang, Taichung City (TW)

(73) Assignee: UNITED MICROELECTRONICS CORP., Hsin-Chu City (TW)

(21) Appl. No.: 18/966,065

(22) Filed: Dec. 2, 2024

(30) Foreign Application Priority Data
Nov. 1, 2024 (TW) 113141813

(51) Int. Cl. H10B 61/00; G11C 11/16; H10N 50/01; H10N 50/10; H10N 50/85

(52) U.S. Cl. CPC H10B 61/22; G11C 11/161; H10N 50/10; H10N 50/85; H10N 50/01

(57) ABSTRACT

A method for fabricating a magnetoresistive random access memory (MRAM) device includes first providing a substrate having a MRAM region and a logic region, forming a first inter-metal dielectric (IMD) layer on the substrate, using a first patterned mask to remove the first IMD layer for forming a first via opening on the MRAM region and a second via opening on the logic region, forming a metal nitride layer in the first via opening and the second via opening, removing part of the metal nitride layer and part of the first IMD layer on the logic region for forming a trench opening, and forming a metal layer in the first via opening, the second via opening, and the trench opening for forming a first metal interconnection on the MRAM region and a second metal interconnection on the logic region.

### BACKGROUND OF THE INVENTION

### 1. Field of the Invention

The invention relates to a magnetoresistive random access memory (MRAM) and method for fabricating the same.

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a magnetoresistive random access memory (MRAM) device includes first providing a substrate having a MRAM region and a logic region, forming a first inter-metal dielectric (IMD) layer on the substrate, using a first patterned mask to remove the first IMD layer for forming a first via opening on the MRAM region and a second via opening on the logic region, forming a metal nitride layer in the first via opening and the second via opening, removing part of the metal nitride layer and part of the first IMD layer on the logic region for forming a trench opening, and forming a metal layer in the first via opening, the second via opening, and the trench opening for forming a first metal interconnection on the MRAM region and a second metal interconnection on the logic region.

According to another aspect of the present invention, a magnetoresistive random access memory (MRAM) device includes a substrate having a MRAM region and a logic region, a first inter-metal dielectric (IMD) layer on the substrate, a first metal interconnection in the first IMD layer on the MRAM, a second metal interconnection in the first IMD layer on the logic region, and a magnetic tunneling junction (MTJ) on the first metal interconnection. Preferably, the first metal interconnection includes a first via conductor and the second metal interconnection includes a second via conductor and a trench conductor on the second via conductor, in which the second via conductor and the trench conductor include different materials.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating a MRAM device according to an embodiment of the present invention.

FIG. 10 illustrates a structural view of a MRAM device according to an embodiment of the present invention.

### DETAILED DESCRIPTION

Referring to FIGS. 1-9, FIGS. 1-9 illustrate a method for fabricating a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region 16 are defined on the substrate 12.

Active devices such as metal-oxide semiconductor (MOS) transistors, passive devices, conductive layers, and interlayer dielectric (ILD) layer 18 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 18 could be formed on the substrate 12 to cover the MOS transistors, and a plurality of contact plugs could be formed in the ILD layer 18 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 20 are formed on the ILD layer 18 on the MRAM region 14 and the edge region 16 to electrically connect the aforementioned contact plugs, in which the metal interconnect structure 20 includes an inter-metal dielectric (IMD) layer 24 and metal interconnections 26 embedded in the IMD layer 24. In this embodiment, each of the metal interconnections 26 from the metal interconnect structure 20 preferably includes a trench conductor and each of the metal interconnections 26 could be embedded within the IMD layer 24 according to a single damascene process or dual damascene process. For instance, each of the metal interconnections 26 could further includes a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 are preferably made of copper and the IMD layer 24 is made of silicon oxide such as tetraethyl orthosilicate (TEOS).

Next, a stop layer 72, another stop layer 74, an IMD layer 76, a hard mask 78, a cap layer 82, and a patterned mask 84 are formed on the IMD layer 24, in which the patterned mask 84 includes openings (not shown) exposing the surface of the cap layer 82 on the MRAM region 14 and the logic region 16. In this embodiment, the stop layer 72 preferably includes silicon carbon nitride (SiCN), the stop layer 74 includes TEOS, the IMD layer 76 includes an ultra low-k (ULK) dielectric layer including but not limited to for example porous material or silicon oxycarbide (SiOC) or SiOCH, the hard mask 78 includes silicon oxynitride (SiON), the cap layer 82 includes silicon oxide, and the patterned mask 84 includes a patterned resist.

Next, an etching process is conducted by using the patterned mask 84 as mask to remove part of the cap layer 82, part of the hard mask 78, part of the IMD layer 76, part of the stop layer 74, and part of the stop layer 72 on the MRAM region 14 and the logic region 16 the same time for forming via openings 98, 100 exposing the metal interconnections 26 underneath.

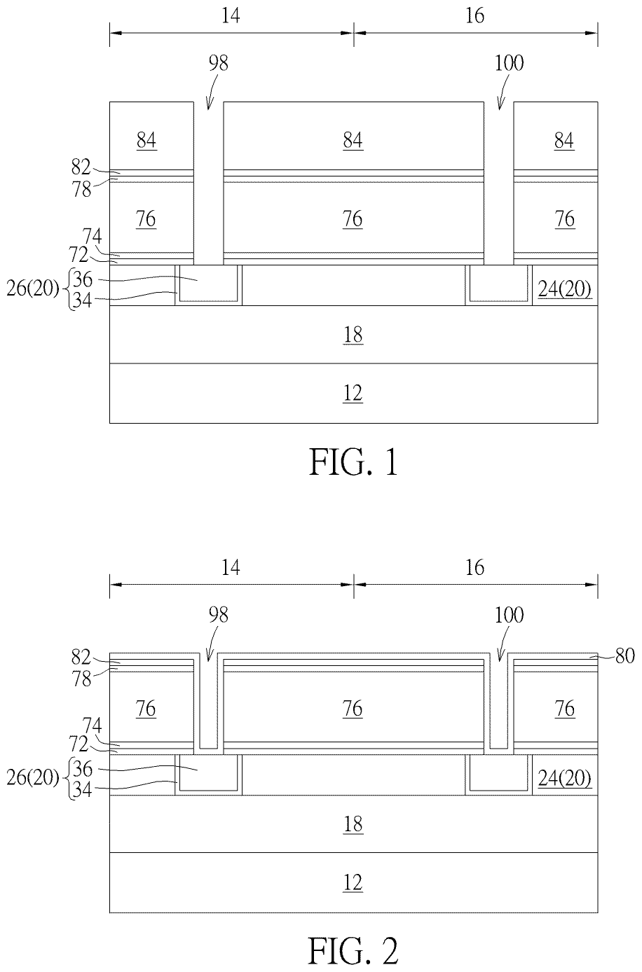

Next, as shown in FIG. 2, the patterned mask 84 is stripped, and then a metal nitride layer 80 is formed on the top surface of the cap layer 82 on the MRAM region 14 and logic region 16, sidewalls of the cap layer 82, sidewalls of the hard mask 78, sidewalls of the IMD layer 76, sidewalls of the stop layer 74, and sidewalls and bottom surface of the stop layer 72, in which the metal nitride layer 80 is deposited into the via openings 98, 100 without filling the via openings 98, 100 completely. In this embodiment, the metal nitride layer 80 preferably includes titanium nitride (TiN), but not limited thereto.

Next, as shown in FIG. 3, another patterned mask 88 is formed on the MRAM region 14 and logic region 16, in which the patterned mask 88 includes an opening (not shown) exposing part of the metal nitride layer 80 on the logic region 16 and the width of the opening is greater than the width of the aforementioned via opening 100. Next, an etching process is conducted by using the patterned mask 88 as mask to remove part of the metal nitride layer 80, part of the cap layer 82, part of the hard mask 78, and part of the IMD layer 76 not covered by the patterned mask 88. This expands the top portion of the via opening 100 on the logic region 16 to form a trench opening 102.

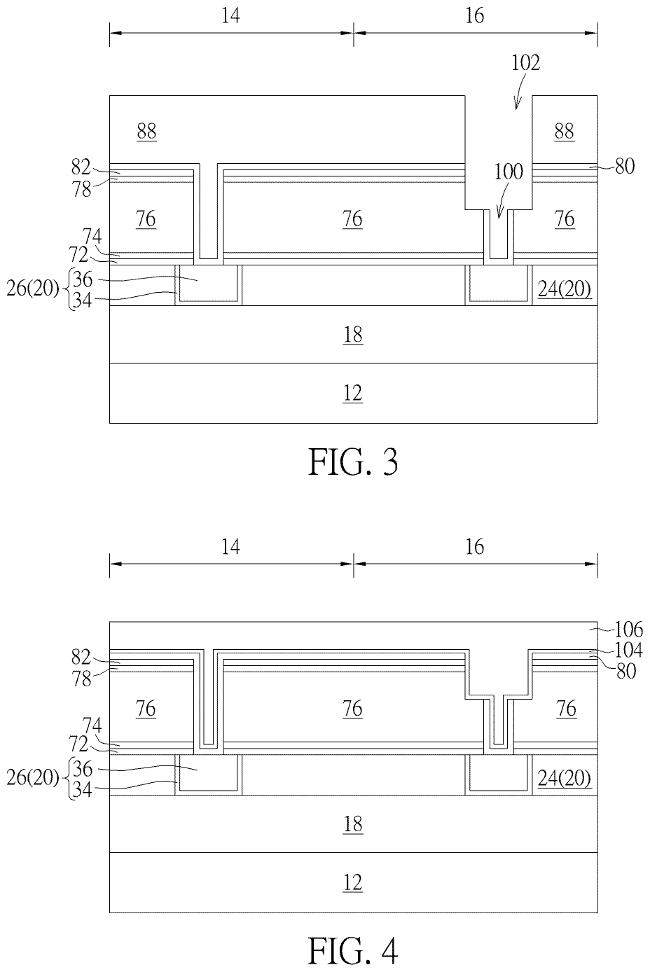

Next, as shown in FIG. 4, the patterned mask 88 is stripped, and then a barrier layer 104 and a metal layer 106 are formed in the via opening 98 on the MRAM region 14 and via opening 100 and trench opening 102 on the logic region 16 to fill each of the openings completely. Preferably, the barrier layer 104 is selected from the group consisting of titanium (Ti), titanium nitride (TiN), tantalum (Ta), and tantalum nitride (TaN) and metal layer 106 is selected from the group consisting of tungsten (W), copper (Cu), aluminum (Al), titanium aluminide (TiAl), and cobalt tungsten phosphide (CoWP).

Next, as shown in FIG. 5, a planarizing process such as chemical mechanical polishing (CMP) process could be conducted to remove part of the metal layer 106, part of the barrier layer 104, all the cap layer 82, and all the hard mask 78 for forming metal interconnections 108 electrically connecting the metal interconnections 26 underneath. Preferably, the metal interconnection 108 on the MRAM region 14 includes a via conductor 110 while the metal interconnection 108 on the logic region 16 includes a via conductor 112 and a trench conductor 114.

It should be noted that the via conductor 112 and the trench conductor 114 formed on the logic region 16 at this stage are preferably made of different materials while the via conductor 112 on the logic region 16 and the via conductor 110 on the MRAM region 14 are made of same material. Specifically, the via conductor 110 on the MRAM region 14 includes a metal nitride layer 80, a barrier layer 104 disposed on the metal nitride layer 80, and a metal layer 106 disposed on the barrier layer 104. The via conductor 112 on the logic region 16 also includes a metal nitride layer 80, a barrier layer 104 disposed on the metal nitride layer 80, and a metal layer 106 disposed on the barrier layer 104 while the trench conductor 114 on the logic region 16 only includes a barrier layer 104 and metal layer 106 disposed on the barrier layer 104. In other words, the via conductor 112 on the logic region 16 includes three material layers while the trench conductor 114 atop only includes two material layers, in which the top surface of the metal nitride layer 80 on the logic region 16 is slightly lower than the top surface of the metal nitride layer 80 on the MRAM region 14 while the top surfaces of the barrier layer 104 and metal layer 106 on the logic region 16 are even with the top surfaces of the barrier layer 104 and metal layer 106 on the MRAM region 14.

Next, another metal interconnect structure 22 is formed on the metal interconnections 108 and IMD layer 76, in which the metal interconnect structure 22 includes a stop layer 28, an IMD layer 30, and a metal interconnection 32 embedded in the stop layer 28 and IMD layer 30. It should be noted that even though the width of the bottom surface and/or top surface of the metal interconnection 32 is slightly greater than the width of the bottom surface and/or top surface of the metal interconnection 108 or via conductor 110 underneath, according to other embodiment of the present invention, the bottom surface or top surface of the metal interconnection 32 and the via conductor 110 underneath could also have same or different widths, which is also within the scope of the present invention.

Similar to the via conductor 110 formed on the MRAM region 14, the metal interconnection 32 formed directly on top of the via conductor 110 also includes a via conductor and the metal interconnection 32 could be embedded within the IMD layer 30 and/or stop layer 28 according to a single damascene process or dual damascene process. For instance, the metal interconnection 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In contrast to the metal layer 36 in the IMD layer 26 includes copper, the metal layer 36 from the metal interconnection 32 at this stage preferably includes tungsten (W), the IMD layer 30 could include silicon oxide such as tetraethyl orthosilicate (TEOS), and the stop layer 28 could include nitrogen doped carbide (NDC), silicon nitride (SiN), or silicon carbon nitride (SiCN).

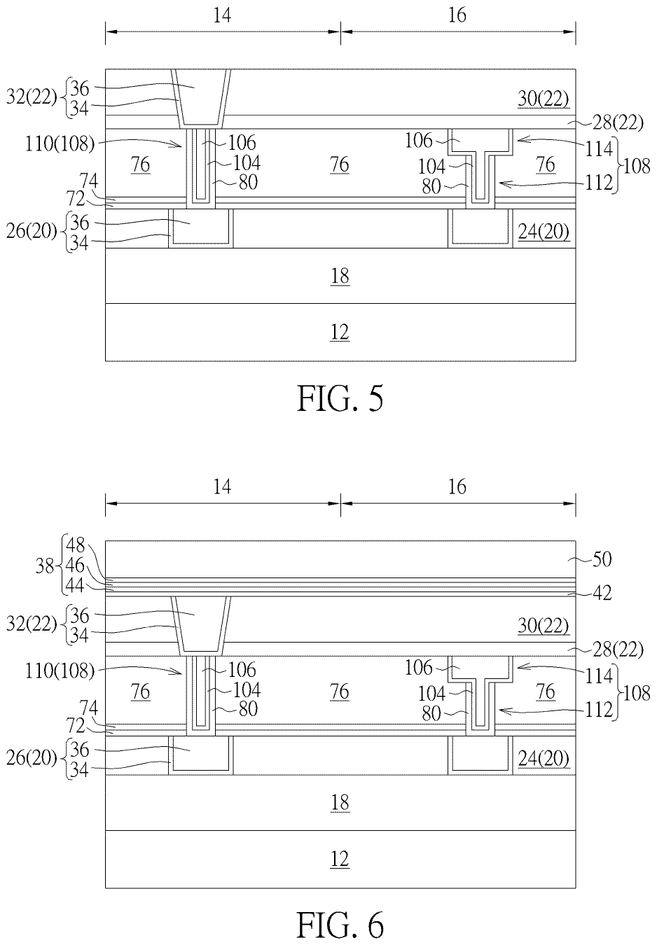

Next, as shown in FIG. 6, a bottom electrode 42, a MTJ stack 38 or stack structure, a top electrode 50, and a patterned mask (not shown) are formed on the metal interconnect structure 22. In this embodiment, the formation of the MTJ stack 38 could be accomplished by sequentially depositing a pinned layer 44, a barrier layer 46, and a free layer 48 on the bottom electrode 42. In this embodiment, the bottom electrode 42 and the top electrode 50 are preferably made of conductive material including but not limited to for example Ta, Pt, Cu, Au, Al, or combination thereof. The pinned layer 44 could be made of ferromagnetic material including but not limited to for example iron, cobalt, nickel, or alloys thereof such as cobalt-iron-boron (CoFeB) or cobalt-iron (CoFe). Moreover, the pinned layer 44 could also be made of antiferromagnetic (AFM) material including but not limited to for example ferromanganese (FeMn), platinum manganese (PtMn), iridium manganese (IrMn), nickel oxide (NiO), or combination thereof, in which the pinned layer 44 is formed to fix or limit the direction of magnetic moment of adjacent layers. The barrier layer 46 could be made of insulating material including but not limited to for example oxides such as aluminum oxide (AlOₓ) or magnesium oxide (MgO). The free layer 48 could be made of ferromagnetic material including but not limited to for example iron, cobalt, nickel, or alloys thereof such as cobalt-iron-boron (CoFeB), in which the magnetized direction of the free layer 48 could be altered freely depending on the influence of outside magnetic field.

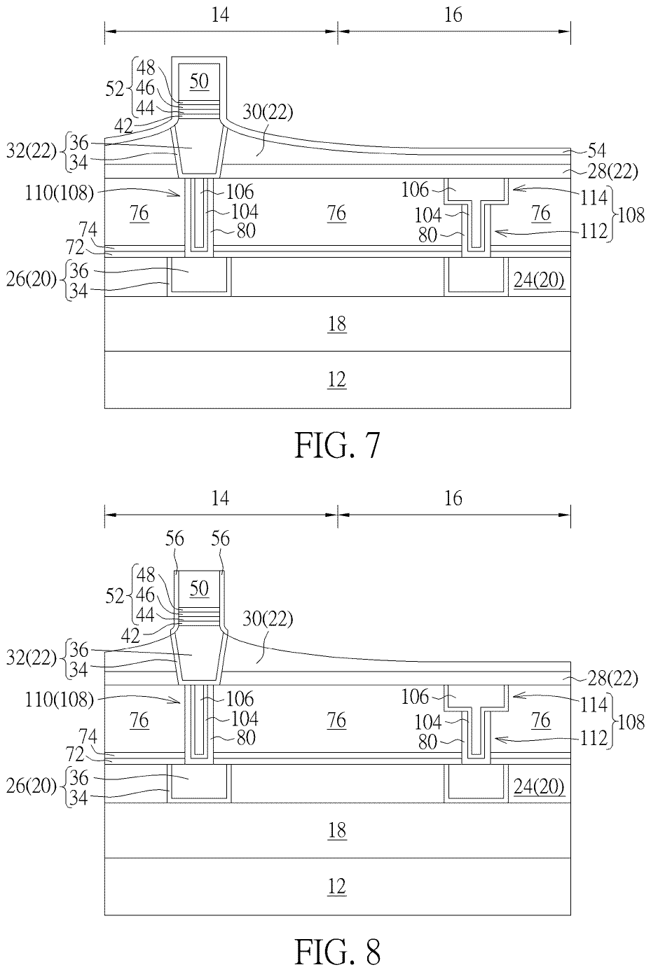

Next, as shown in FIG. 7, one or more etching process is conducted by using the patterned mask as mask to remove part of the top electrode 50, part of the MTJ stack 38, part of the bottom electrode 42, and part of the IMD layer 30 to form a MTJ 52 on the MRAM region 14. It should be noted that a reactive ion etching (RIE) and/or an ion beam etching (IBE) process is conducted to remove the top electrode 50, MTJ stack 38, bottom electrode 42, and the IMD layer 30 in this embodiment for forming the MTJ 52. Due to the characteristics of the IBE process, the top surface of the remaining IMD layer 30 is slightly lower than the top surface of the metal interconnections 32 after the IBE process and the top surface of the IMD layer 30 also reveals a curve or an arc. It should also be noted that as the IBE process is conducted to remove part of the IMD layer 30, part of the metal interconnection 32 is removed at the same time to form inclined sidewalls on the surface of the metal interconnection 32 immediately adjacent to the MTJ 52.

Next, a cap layer 54 is formed on the MTJ 52 while covering the surface of the IMD layer 30. In this embodiment, the cap layer 54 preferably includes silicon nitride, but could also include other dielectric material including but not limited to for example silicon oxide, silicon oxynitride (SiON), or silicon carbon nitride (SiCN).

Next, as shown in FIG. 8, an etching process is conducted to remove part of the cap layer 54 to form a spacer 56 around the MTJ 52 while covering and directly contacting the inclined sidewalls of the metal interconnection 32.

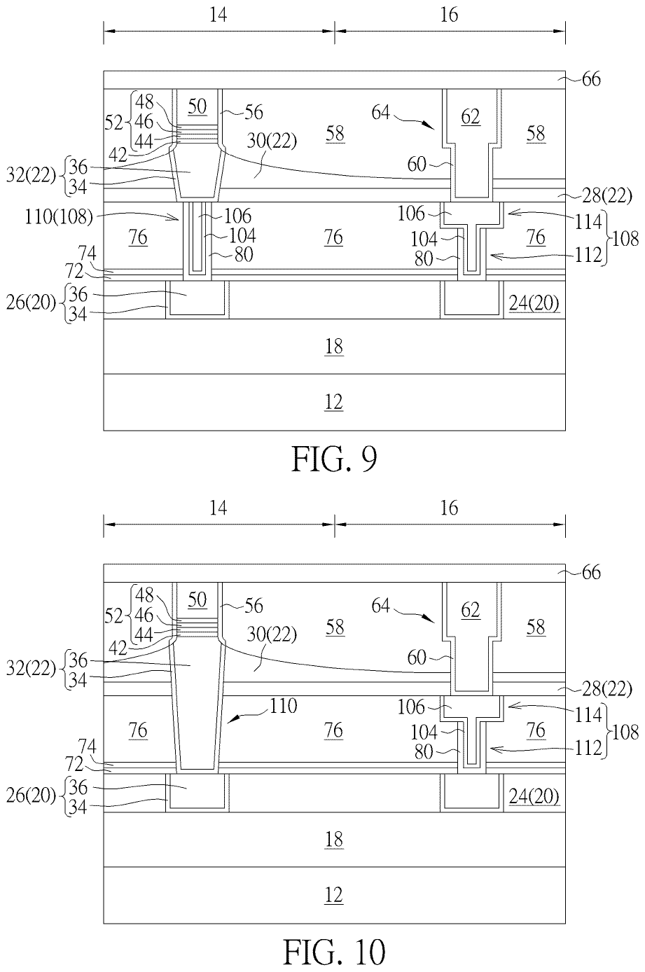

Next, as shown in FIG. 9, another IMD layer 58 is formed on the MRAM region 14 and logic region 16, and a planarizing process such as CMP is conducted to remove part of the IMD layer 58 so that the top surface of the IMD layer 58 is even with the top surface of the top electrode 50. Next, a pattern transfer or dual damascene process is conducted by using a patterned mask (not shown) to remove part of the IMD layer 58 on the logic region 16 to form a contact hole (not shown) exposing the metal interconnection 108 underneath and conductive materials are deposited into the contact hole afterwards. For instance, a barrier layer 60 selected from the group consisting of titanium (Ti), titanium nitride (TiN), tantalum (Ta), and tantalum nitride (TaN) and metal layer 62 selected from the group consisting of tungsten (W), copper (Cu), aluminum (Al), titanium aluminide (TiAl), and cobalt tungsten phosphide (CoWP) could be deposited into the contact hole, and a planarizing process such as CMP could be conducted to remove part of the conductive materials including the aforementioned barrier layer 60 and metal layer 62 to form a metal interconnection 64 in the contact hole electrically connecting the metal interconnection 108. Similar to the metal interconnection 108, the metal interconnection 64 also includes a via conductor and a trench conductor. Next, a stop layer 66 is formed on the IMD layer 58 and metal interconnection 64, in which the stop layer 66 could include silicon oxide, silicon nitride, or SiCN.

Referring again to FIG. 10, FIG. 10 further illustrates a structural view of a MRAM device according to an embodiment of the present invention. As shown in FIG. 10, in contrast to the aforementioned embodiment of forming metal interconnections 108 in the IMD layer 76 on both MRAM region 14 and logic region 16 at the same, it would also be desirable to follow the processes conducted in FIGS. 1-5 by only forming a metal interconnection 108 in the IMD layer 76 on the logic region 16, form the stop layer 28 and IMD layer 30 according to FIG. 5, and then form a metal interconnection 32 on the MRAM region 14 such that the metal interconnection 32 penetrates the IMD layer 30, the stop layer 28, the lower level IMD layer 76, the stop layer 74, and the stop layer 72 at the same time and directly contacting the even lower metal interconnection 26. Next, processes conducted in FIGS. 6-9 could be carried out to form a MTJ 52 on the metal interconnection 32, form an IMD layer 58 around the MTJ 52, and then form a metal interconnection 64 in the IMD layer 58 on the logic region 16.

In other words, in contrast to the aforementioned embodiment in FIG. 9 of having two sets of via conductors 32, 110 with same or different widths in the IMD layers 30, 76 directly under the MTJ 52 for connecting the lower metal interconnection 26, the present embodiment forms a metal interconnection 32 made of a single via conductor 110 directly under the MTJ 52 and penetrating the two IMD layers 30, 76 for connecting the lower level metal interconnection 26 and the MTJ 52. Preferably, the bottom surface of the metal interconnection 32 is even with the bottom surface of the 108 on the logic region 16 and the top surface of the metal interconnection 32 is higher than the bottom surface of the metal interconnection 64 on the logic region 16 but could also be higher than, even with, or lower than the boundary or interconnecting spot between via conductor and trench conductor of the metal interconnection 64. Similar to the aforementioned embodiment, the metal interconnection 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP), and the metal layer 36 directly under the MTJ 52 preferably includes tungsten (W).

Overall, the present invention preferably forms an additional level of metal interconnections 108 between the metal interconnection 32 directly under a MTJ 52 and a lower level metal interconnection 26 on the MRAM region 14 and logic region 16, in which metal interconnections 108 between the metal interconnection 26 and the metal interconnection 32 directly under MTJ 52 on the MRAM region 14 is preferably a via conductor while the same level metal interconnection 108 on the logic region 16 is made of a combination of via conductor 112 and trench conductor 114. Moreover, according to another embodiment shown in FIG. 10 of the present invention, it would also be desirable to form a metal interconnection 32 made of a single via conductor 110 directly under the MTJ 52 and penetrating two ILD layers 30, 76 for connecting the lower level metal interconnection 26 and MTJ 52. According to a preferred embodiment of the present invention, the above design could improve issues such as excessive IMD layer loading caused by IBE process and significant height difference between MRAM region and logic region such that there is an urgent need for lowering the height of MTJ as semiconductor process advances from 22 nm node into 14 nm node.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a magnetoresistive random access memory (MRAM) device, comprising:
providing a substrate having a MRAM region and a logic region;
forming a first inter-metal dielectric (IMD) layer on the substrate;
using a first patterned mask to remove the first IMD layer for forming a first via opening on the MRAM region and a second via opening on the logic region;
forming a metal nitride layer in the first via opening and the second via opening;
removing part of the metal nitride layer and part of the first IMD layer on the logic region for forming a trench opening;
forming a metal layer in the first via opening, the second via opening, and the trench opening for forming a first metal interconnection on the MRAM region and a second metal interconnection on the logic region; and
forming a magnetic tunneling junction (MTJ) on the first metal interconnection.

2. The method of claim 1, further comprising:
forming a hard mask on the first IMD layer;
using the first patterned mask to remove the hard mask and the first IMD layer for forming the first via opening on the MRAM region and the second via opening on the logic region;
forming the metal nitride layer in the first via opening and the second via opening;
using a second patterned mask to remove part of the metal nitride layer and part of the first IMD layer on the logic region for forming the trench opening;
forming the metal layer in the first via opening, the second via opening, and the trench opening; and
planarizing the metal layer for forming the first metal interconnection on the MRAM region and the second metal interconnection on the logic region.

3. The method of claim 2, wherein the first metal interconnection comprises a first via conductor.

4. The method of claim 3, wherein the first via conductor comprises:
the metal nitride layer;
a barrier layer on the metal nitride layer; and
the metal layer on the barrier layer.

5. The method of claim 2, wherein the second metal interconnection comprises:
a second via conductor; and
a trench conductor on the second via conductor.

6. The method of claim 5, wherein the second via conductor comprises:
the metal nitride layer;
a barrier layer on the metal nitride layer; and
the metal layer on the barrier layer.

7. The method of claim 5, wherein the trench conductor comprises:
a barrier layer; and
the metal layer on the barrier layer.

8. The method of claim 1, further comprising:
forming a second IMD layer on the first IMD layer;
forming a third metal interconnection on the first metal interconnection; and
forming the MTJ on the third metal interconnection.

9. The method of claim 8, wherein the third metal interconnection comprises a via conductor.

10. The method of claim 1, wherein the metal nitride layer comprises titanium nitride (TiN).

11. A magnetoresistive random access memory (MRAM) device, comprising:
a substrate having a MRAM region and a logic region;
a first inter-metal dielectric (IMD) layer on the substrate;
a first metal interconnection in the first IMD layer on the MRAM, wherein the first metal interconnection comprises a first via conductor;
a second metal interconnection in the first IMD layer on the logic region, wherein the second metal interconnection comprises:
a second via conductor;
a trench conductor on the second via conductor, wherein the second via conductor and the trench conductor comprise different materials; and
a magnetic tunneling junction (MTJ) on the first metal interconnection.

12. The MRAM device of claim 11, further comprising:
a second IMD layer on the first IMD layer;
a third metal interconnection on the first metal interconnection; and
the MTJ on the third metal interconnection.

13. The MRAM device of claim 12, wherein the third metal interconnection comprises a third via conductor.

14. The MRAM device of claim 12, further comprising:
a third IMD layer on the second IMD layer and around the MTJ;
a fourth metal interconnection on the second metal interconnection.

15. The MRAM device of claim 14, wherein the fourth metal interconnection comprises:
a fourth via conductor; and
a second trench conductor on the fourth via conductor.

16. The MRAM device of claim 11, wherein the second via conductor comprises:
a metal nitride layer;
a barrier layer on the metal nitride layer; and
a metal layer on the barrier layer.

17. The MRAM device of claim 11, wherein the trench conductor comprises:
a barrier layer; and
a metal layer on the barrier layer.
